(19) United States
(12) Patent Application Publication
(10) Pub. No.: US 2016/0336514 A1
(43) Pub. Date: Nov. 17, 2016

(54) POLYMER AND ORGANIC LIGHT-EMITTING DEVICE

(71) Applicants: Cambridge Display Technology Limited, Godmanchester (GB); Sumitomo Chemical Company Limited, Tokyo (JP)

(72) Inventors: Ruth Pegington, Godmanchester (GB); Martin Humphries, Godmanchester (GB)

(73) Assignees: Cambridge Display Technology Limited, Godmanchester (GB); Sumitomo Chemical Company Limited, Tokyo (JP)

(21) Appl. No.: 15/153,481

(22) Filed: May 12, 2016

(30) Foreign Application Priority Data
May 15, 2015 (GB) 1508440.3

(51) Int. Cl. H01L 51/00; C08G 73/02

(52) U.S. Cl. CPC H01L 51/0039; H01L 51/0043; C08G 73/026; H01L 51/5206

(57) ABSTRACT

A block copolymer comprising a first block and a second block wherein the first block comprises a repeat unit of formula (I) and the second block comprises a repeat unit of formula (II):

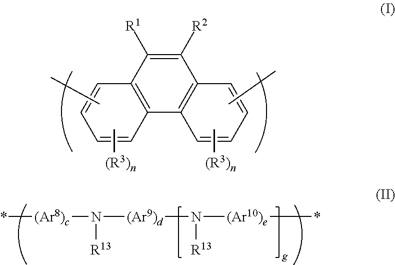

wherein R¹ and R² are independently H or a substituent; R³ independently in each occurrence is a substituent; each n is independently 0, 1, 2 or 3; Ar⁸, Ar⁹ and Ar¹⁰ independently in each occurrence is an aryl or heteroaryl group that may be unsubstituted or substituted with one or more substituents; R¹³ independently in each occurrence is a substituent; c, d and e are each independently at least 1; and g is 0 or a positive integer. The block copolymer may be used as a light-emitting material in an organic light-emitting device.

### RELATED APPLICATIONS

This application claims foreign priority benefits under 35 U.S.C. §119(a)-(d) or 35 U.S.C. §365(b) of British application number 1508440.3, filed May 15, 2015, the entirety of which is herein incorporated by reference.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton).

Phosphorescent dopants are also known (that is, a light-emitting dopant in which light is emitted via decay of a triplet exciton).

A hole-transporting layer may be provided between the anode and light-emitting layer of an OLED.

Light-emitting materials include small molecule, polymeric and dendrimeric materials. Suitable light-emitting polymers include poly(arylene vinylenes) such as poly(p-phenylene vinylenes) and polymers containing arylene repeat units, such as fluorene repeat units.

A layer of an OLED, e.g. the light-emitting layer, may be formed by depositing a formulation containing the materials of the layer and a solvent followed by evaporation of the solvent, which requires use of soluble organic polymer materials allowing solution processing in device manufacture.

US2007/205714 discloses polymers comprising at least 5 mol % of repeat units of the following formula:

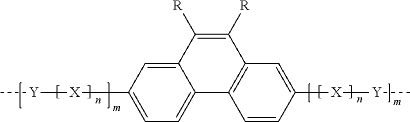

wherein X is —CR¹═CR¹—, C≡C or N—Ar and Y is a divalent aromatic or heteroaromatic ring system having 2 to 40 C atoms.

US 2006/229427 discloses conjugated polymers comprising blocks which are linked by random or partly random sections.

“Copolymer” as used herein means a polymer comprising two or more different repeat units.

### SUMMARY OF THE INVENTION

In a first aspect the invention provides a block copolymer comprising a first block and a second block wherein the first block comprises a repeat unit of formula (I) and the second block comprises a repeat unit of formula (II):

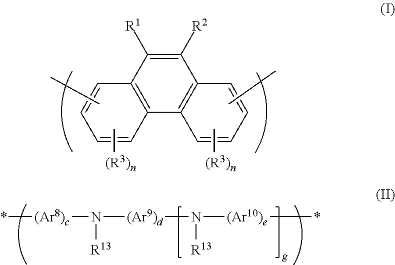

wherein R¹ and R² are independently H or a substituent;

R³ independently in each occurrence is a substituent;

each n is independently 0, 1, 2 or 3;

Ar⁸, Ar⁹ and Ar¹⁰ independently in each occurrence is an aryl or heteroaryl group that may be unsubstituted or substituted with one or more substituents;

R¹³ independently in each occurrence is a substituent;

c, d and e are each independently at least 1; and

g is 0 or a positive integer.

In a second aspect the invention provides a method of forming a block copolymer according to the first aspect wherein monomers for forming one of the first and second blocks are reacted to form said first or second block, and reacting said first or second block with monomers for forming the other of the first and second block.

In a third aspect the invention provides an organic electronic device comprising an anode, a cathode and at least one organic semiconducting layer between the anode and cathode wherein at least one of the organic semiconducting layers comprises a block copolymer according to the first aspect.

In a fourth aspect the invention provides an ink formulation comprising a block copolymer according to the first aspect and at least one solvent.

In a fifth aspect the invention provides a method of forming an organic light-emitting device according to the third aspect, the method comprising the step of forming an organic semiconducting layer of the device by depositing an ink according to the fourth aspect.

### DESCRIPTION OF THE DRAWINGS

The invention will now be described in more detail with reference to the drawings in which:

FIG. 1 illustrates schematically an OLED according to an embodiment of the invention;

FIG. 2 is a graph of brightness vs. luminance for a device according to an embodiment of the invention and a comparative device; and

FIG. 3 is a graph of external quantum efficiency vs. current density for a device according to an embodiment of the invention and a comparative device.

### DETAILED DESCRIPTION OF THE INVENTION

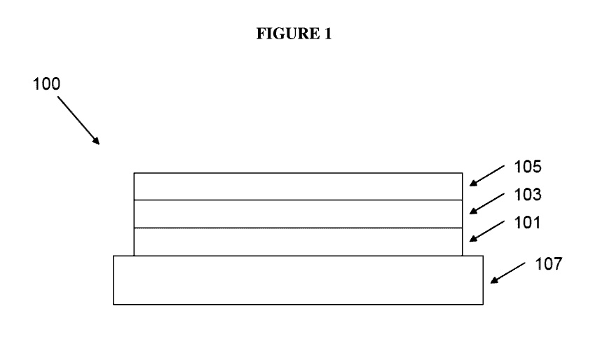

FIG. 1 illustrates an OLED 100 according to an embodiment of the invention comprising an anode 101, a cathode 105 and a light-emitting layer 103 between the anode and cathode. The device 100 is supported on a substrate 107, for example a glass or plastic substrate.

One or more further layers may be provided between the anode 101 and cathode 105, for example hole-transporting layers, electron transporting layers, hole blocking layers and electron blocking layers. The device may contain more than one light-emitting layer.

Preferred device structures include:

Anode/Hole-injection layer/Light-emitting layer/Cathode

Anode/Hole transporting layer/Light-emitting layer/Cathode

Anode/Hole-injection layer/Hole-transporting layer/Light-emitting layer/Cathode

Anode/Hole-injection layer/Hole-transporting layer/Light-emitting layer/Electron-transporting layer/Cathode.

At least one of a hole-transporting layer and hole injection layer may be present. Optionally, both a hole injection layer and hole-transporting layer are present.

A block copolymer as described in the first aspect is provided in a layer of the device. The polymer may be provided in one or more of light-emitting layer 103; a hole-transporting layer; an electron-transporting layer; and a charge-blocking layer.

A layer containing a polymer according to the first aspect may consist essentially of the polymer, or the polymer may be mixed with one or more further materials.

Preferably, the polymer is present in light-emitting layer 103 in which case the polymer may emit light itself when in operation, or it may function as a host material used in combination with one or more fluorescent or phosphorescent dopants of the light-emitting layer.

A layer of the device comprising the polymer described herein may be formed by depositing a solution of the polymer and evaporating the solvents of the solution. Exemplary methods for depositing the solution are spin-coating, dip-coating, doctor blade coating, flexographic printing and inkjet printing. Preferably, the layer comprising the polymer is formed by inkjet printing.

A light-emitting layer of the device may be inkjet printed by providing at least one patterned insulating layer over the anode and defining wells for printing of one colour (in the case of a monochrome device) or multiple colours (in the case of a multicolour, in particular full colour device). If the device comprises one or more layers between the anode and the light emitting layer then each of the one or more layers is preferably also inkjet printed.

The patterned layer or layers may each be a layer of photoresist that is patterned to define a well for each pixel or subpixel of the device as described in, for example, EP 0880303.

As an alternative to wells, the ink may be printed into channels defined by a patterned layer or layers. In particular, the insulating layer or layers may be patterned to form channels which, unlike wells, extend over a plurality of pixels and which may be closed or open at the channel ends.

The present inventors have found that polymers comprising phenanthrene units may display poor solution processing characteristics. Without wishing to be bound by any theory, it is believed that chains of polymers comprising phenanthrene repeat units may have a tendency to aggregate.

The present inventors have surprisingly found that block polymers containing phenanthrene units in one block and amine units in another block may show superior solution processing characteristics as compared to a polymer comprising randomly distributed phenanthrene and amine repeat units.

Preferably, the block copolymer as described herein comprises a plurality of blocks of each of the first block and the second block. It will be appreciated that blocks of each of the first and second blocks may be of varying length.

The polymer comprises a repeat unit of formula (I):

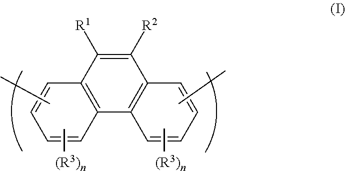

R¹ and R² may each independently be selected from:
a branched, linear or cyclic C₁₋₃₀ alkyl wherein one or more non-adjacent C atoms may be replaced with O, S, C═O and —COO—, and wherein one or more H atoms of the C₁₋₂₀ alkyl may be replaced with F; and
a group of formula —(Ar¹)ₚ wherein Ar¹ in each occurrence is independently an aromatic or heteroaromatic group that may be unsubstituted or substituted with one or more substituents; and p is at least 1, optionally 1, 2 or 3.

Optionally Ar¹, in each occurrence when p is more than 1, is phenyl that independently in each occurrence may be unsubstituted or substituted with one or more substituents.

Optionally, an Ar¹ group bound directly to the phenanthrene of formula (I) is an aryl group and one or both of the carbon atoms of the aryl group that are adjacent to the carbon atom of Ar¹ bound to the phenanthrene of formula (I) are substituted with a substituent.

Optionally, substituents of Ar¹, either on a carbon atom of Ar¹ adjacent to a carbon atom of Ar¹ bound to the phenanthrene of formula (I) or elsewhere on Ar¹, are selected from the group consisting of branched, linear or cyclic C₁₋₃₀ alkyl wherein one or more non-adjacent C atoms may be replaced with O, S, C═O and —COO—, and wherein one or more H atoms of the C₁₋₂₀ alkyl may be replaced with F.

R¹ and R² are preferably selected from C₁₋₄₀ hydrocarbyl groups and more preferably from the group consisting of C₁₋₂₀ alkyl and C₆₋₂₀ aryl, preferably phenyl, that may be unsubstituted or substituted with one or more C₁₋₁₀ alkyl groups.

R¹ and R² may be the same or different. Optionally, R¹ is a C₁₋₂₀ alkyl group and R² is a group of formula —(Ar¹)ₚ.

R³, where present, is optionally selected from C₁₋₂₀ alkyl wherein one or more non-adjacent C atoms may be replaced with O, S, C═O and —COO—, optionally substituted aryl, optionally substituted heteroaryl. Particularly preferred substituents include C₁₋₂₀ alkyl and substituted or unsubstituted aryl, for example phenyl. Optional substituents for the aryl include one or more C₁₋₂₀ alkyl groups.

Preferably, each n is 0.

Optionally, the repeat unit of formula (I) has formula (Ia):

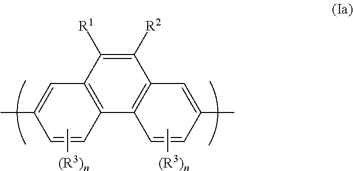

Optionally, the polymer comprises 0.5 mol % up to about 90 mol %, optionally about 1-50 mol %, optionally about 10-50 mol % of repeat units of formula (I), optionally about 20-25 mol %.

The polymer of the first aspect comprises repeat units of formula (II):

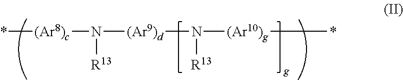

wherein Ar⁸, Ar⁹ and Ar¹⁰ in each occurrence are independently selected from substituted or unsubstituted aryl or heteroaryl; g is 0 or a positive integer, preferably 0 or 1, R¹³ is H or a substituent, preferably a substituent, and c, d and e are each independently 1, 2 or 3.

R¹³, which may be the same or different in each occurrence when g is a positive integer, is preferably selected from the group consisting of alkyl, optionally C₁₋₂₀ alkyl; a crosslinkable unit, optionally a benzocyclobutene unit; and —(Ar¹¹)ₜ wherein Ar¹¹ in each occurrence is independently an aryl or heteroaryl group that is unsubstituted or substituted with one or more substituents and t is at least 1, optionally 1, 2 or 3. R¹³ is preferably a C₁₋₄₀ hydrocarbyl group, more preferably a C₁₋₄₀ hydrocarbyl group of formula —(Ar¹¹)ₜ.

Any of Ar⁸, Ar⁹ and, if present, Ar¹⁰ and Ar¹¹ bound directly to a N atom in the repeat unit of Formula (II) may be linked by a direct bond or a divalent linking atom or group to another of Ar⁸, Ar⁹, Ar¹⁰ and Ar¹¹ directly bound to the same N atom. Preferred divalent linking atoms and groups include O, S, NR⁹ and CR⁹₂, wherein each R⁹ is independently selected from the group consisting of alkyl, preferably C₁₋₂₀ alkyl; and aryl or heteroaryl, preferably phenyl, that may be unsubstituted or substituted with one or more C₁₋₂₀ alkyl groups.

Ar⁸, Ar⁹, Ar¹⁰ and Ar¹¹ are preferably each independently a C₆₋₂₀ aryl group, optionally phenyl or a C₁₀₋₂₀ polycyclic aromatic group. Exemplary polycyclic aromatic groups are naphthalene, perylene, anthracene and fluorene.

Any of Ar⁸, Ar⁹ and, if present, Ar¹⁰ and Ar¹¹ may be substituted with one or more substituents. Exemplary substituents are substituents R¹⁰, wherein each R¹⁰ may independently be selected from the group consisting of:
substituted or unsubstituted alkyl, optionally C₁₋₂₀ alkyl, wherein one or more non-adjacent C atoms may be replaced with optionally substituted aryl or heteroaryl, O, S, substituted N, C═O or —COO— and one or more H atoms may be replaced with F; and
a crosslinkable group, for example a group comprising a double bond such and a vinyl or acrylate group.

Preferred repeat units of formula (II) have formulae 1-3:

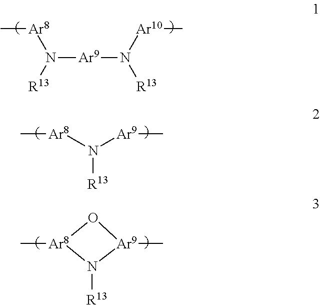

In one preferred arrangement, R¹³ is Ar¹¹ and each of Ar⁸, Ar⁹ and Ar¹⁰ and Ar¹¹ are independently unsubstituted or substituted with one or more C₁₋₂₀ alkyl groups.

In a preferred embodiment, Ar⁸, Ar¹⁰ and Ar¹¹ of formula (II-1) are each unsubstituted or substituted phenyl and Ar⁹ of formula (II-1) is unsubstituted or substituted phenyl or an unsubstituted or substituted C₁₀₋₂₀ polycyclic aromatic group.

Ar⁸ and Ar⁹ of formulae (II-2) and (II-3) are preferably phenyl, each of which may be unsubstituted or substituted with one or more substituents R¹⁰, more preferably C₁₋₂₀ alkyl groups, and R¹³ is —(Ar¹¹)ₜ, optionally phenyl, biphenyl or 3,5-diphenylbenzene wherein each phenyl may be unsubstituted or substituted with one or more substituents R¹⁰, more preferably unsubstituted or substituted with one or more C₁₋₂₀ alkyl groups.

Repeat units of formula (II) may be provided in a molar amount in the range of about 0.5 mol % up to about 50 mol %, optionally about 1-25 mol %, optionally about 1-10 mol %.

The polymer may contain one, two or more different repeat units of formula (II).

Amine repeat units may provide hole-transporting and/or light-emitting functionality.

The repeat units of the polymer of the first aspect may consist of repeat units of formula (I) and (II) or may comprise one or more further repeat units.

Exemplary further repeat units include units of formula Ar wherein Ar is an arylene or heteroarylene repeat unit other than repeat units of formula (I) which may be unsubstituted or substituted with one or more substituents.

Exemplary arylene further repeat units Ar include C₆₋₃₀ arylene repeat units that may be unsubstituted or substituted with one or more substituents, optionally arylene repeat units selected from phenylene, fluorene, indenofluorene, naphthalene, anthracene, pyrene repeat and perylene repeat units, each of which may be unsubstituted or substituted with one or more substitutents, for example one or more C₁₋₃₀ hydrocarbyl substituents.

Each of these arylene repeat units may be linked to adjacent repeat units through any two of the aromatic carbon atoms of these units. Specific exemplary linkages include 1,2-, 1,3- or 1,4-phenylene, 3,6- or 2,7-linked fluorene; 9,10-anthracene; 2,6-anthracene; 1,4-naphthalene; 2,6-naphthalene; and 2,5-perylene.

One preferred class of arylene repeat units is phenylene repeat units, such as phenylene repeat units of formula (VI):

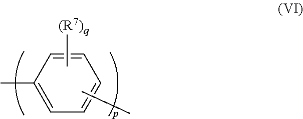

wherein q in each occurrence is independently 0, 1, 2, 3 or 4, optionally 1 or 2; p is 1, 2 or 3; and R⁷ independently in each occurrence is a substituent.

Where present, each R⁷ may independently be selected from the group consisting of:
alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F;
a group of formula —(Ar³)ᵣ wherein each Ar³ is independently an aryl or heteroaryl group, preferably phenyl, and r is at least 1, optionally 1, 2 or 3; and
a crosslinkable-group, for example a group comprising a double bond such and a vinyl or acrylate group, or a benzocyclobutane group.

The or each aryl or heteroaryl group Ar³ may be substituted with one or more substituents R⁸ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F;
NR⁹₂, OR⁹, SR⁹, SiR⁹₃ and
fluorine, nitro and cyano;

wherein each R⁹ is independently selected from the group consisting of alkyl, preferably C₁₋₂₀ alkyl; and aryl or heteroaryl, preferably phenyl, optionally substituted with one or more C₁₋₂₀ alkyl groups.

Substituted N, where present, may be —NR⁹— wherein R⁹ is as described above.

Preferably, each R⁷, where present, is independently selected from C₁₋₄₀ hydrocarbyl, and is more preferably selected from C₁₋₂₀ alkyl; unsubstituted phenyl; phenyl substituted with one or more C₁₋₂₀ alkyl groups; a linear or branched chain of phenyl groups, wherein each phenyl may be unsubstituted or substituted with one or more substituents; and a crosslinkable group.

If p is 1 then exemplary repeat units of formula (VI) include the following:

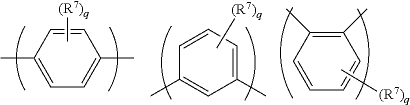

A particularly preferred repeat unit of formula (VI) has formula (VIa):

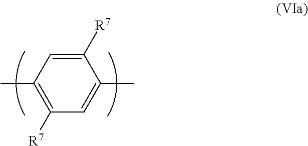

Substituents R⁷ of formula (VIa) are adjacent to linking positions of the repeat unit, which may cause steric hindrance between the repeat unit of formula (VIa) and adjacent repeat units, resulting in the repeat unit of formula (VIa) twisting out of plane relative to one or both adjacent repeat units.

Exemplary repeat units where p is 2 or 3 include the following:

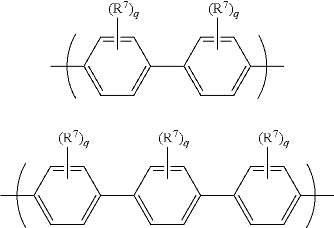

A preferred repeat unit has formula (VIb):

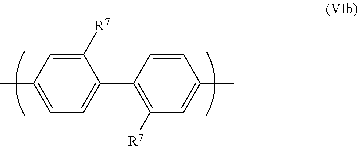

The two R⁷ groups of formula (VIb) may cause steric hindrance between the phenyl rings they are bound to, resulting in twisting of the two phenyl rings relative to one another.

In one optional embodiment, the repeat unit of formula (I) may be the only polycyclic aromatic repeat unit of the polymer. In another optional embodiment, the polymer may contain one or more polycyclic aromatic repeat units in addition to the repeat unit of formula (I).

An exemplary further polycyclic aromatic repeat unit is optionally substituted fluorene, such as repeat units of formula (VII):

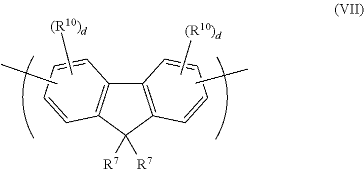

wherein R⁷ in each occurrence is the same or different and is a substituent as described with reference to formula (VI), and wherein the two groups R⁷ may be linked to form a ring; R¹⁰ is a substituent; and d is 0, 1, 2 or 3.

Different substituents R⁷ may be as described in WO 2012/104579, the contents of which are incorporated herein by reference.

The aromatic carbon atoms of the fluorene repeat unit may be unsubstituted, or may be substituted with one or more substituents R¹⁰. Exemplary substituents R¹⁰ are alkyl, for example C₁₋₂₀ alkyl, wherein one or more non-adjacent C atoms may be replaced with O, S, substituted N, C═O and —COO—, optionally substituted aryl, optionally substituted heteroaryl, fluorine and cyano. Particularly preferred substituents include C₁₋₂₀ alkyl and substituted or unsubstituted aryl, for example phenyl. Optional substituents for the aryl include one or more C₁₋₂₀ alkyl groups.

Substituted N, where present, may be —NR¹¹— wherein R¹¹ is C₁₋₂₀ alkyl; unsubstituted phenyl; or phenyl substituted with one or more C₁₋₂₀ alkyl groups.

The extent of conjugation of repeat units of formula (VII) to aryl or heteroaryl groups of adjacent repeat units may be controlled by (a) linking the repeat unit through the 3- and/or 6-positions to limit the extent of conjugation across the repeat unit, and/or (b) substituting the repeat unit with one or more substituents R¹⁰ in or more positions adjacent to the linking positions in order to create a twist with the adjacent repeat unit or units, for example a 2,7-linked fluorene carrying a C₁₋₂₀ alkyl substituent in one or both of the 3- and 6-positions.

The repeat unit of formula (VII) may be an optionally substituted 2,7-linked repeat unit of formula (VIIa):

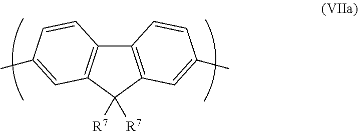

Optionally, the repeat unit of formula (VIIa) is not substituted in a position adjacent to the 2- or 7-position. Linkage through the 2- and 7-positions and absence of substituents adjacent to these linking positions provides a repeat unit that is capable of providing a relatively high degree of conjugation across the repeat unit.

The repeat unit of formula (VII) may be an optionally substituted 3,6-linked repeat unit of formula (VIIb)

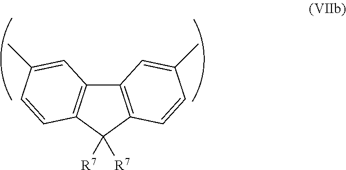

The extent of conjugation across a repeat unit of formula (VIIb) may be relatively low as compared to a repeat unit of formula (VIIa).

Another exemplary further polycyclic aromatic ring system has formula (VIII) wherein R⁷, R¹⁰ and d are each independently as described with reference to Formula (VII), and wherein two groups R⁷ may be linked to form an unsubstituted or substituted ring, for example a ring substituted with one or more C₁₋₂₀ alkyl groups:

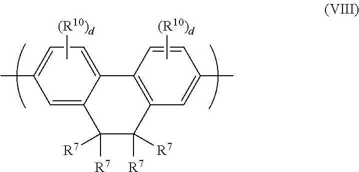

Optionally, no more than 5 mol % of the repeat units of the first block are repeat units of formula (II). Optionally, the first block of the polymer is substantially free of repeat units of formula (II). Optionally, the first block comprises repeat units of formula (I) alone or with one or more further aromatic repeat units Ar.

Optionally, no more than 5 mol % of the repeat units of the second block are repeat units of formula (I). Optionally, the second block of the polymer is substantially free of repeat units of formula (I).

Optionally, the second block comprises, or consists of, repeat units of formula (II) and arylene repeat units, preferably arylene repeat units Ar other than units of formula (I).

Optionally, the second block comprises a chain of alternating repeat units of formula (II) and repeat units of formula Ar.

The polymers as described anywhere herein are suitably amorphous polymers.

Polymers according to the first aspect suitably have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of the polymers of the first aspect may be 1×10³ to 1×10⁸, and preferably 1×10⁴ to 1×10⁷.

Preferably Mw of a polymer for inkjet printing is in the range of 50,000-500,000 Da, optionally 100,000-500,000 Da, optionally 100,000-300,000 Da.

The weight-average molecular weight of the first block is preferably in the range of 10,000-30,000 Da, optionally 15,000-25,000 Da. The Mw of the first block may be measured during its formation and monomers for formation of the second block may be added once the Mw of the first block has reached a predetermined value.

Polymer Synthesis

A preferred method for preparation of polymers as described herein is Suzuki polymerisation as described in, for example, WO 00/53656.

Preferably, the polymer is formed by reacting monomers having two (or more than two) LG1 groups and monomers having two (or more than two) LG2 groups wherein one of LG1 and LG2 is as boronic acid or boronic ester group and the other of LG1 and LG2 is halogen, sulfonic acid or sulfonic ester, optionally tosylate, mesylate or triflate. Each of LG1 and LG2 is bound to a carbon atom of an aryl or heteroaryl group of a monomer and the monomers are polymerised to form a carbon-carbon bond between the aryl or heteroaryl groups of the monomers.

It will be understood that reaction of monomers having two LG1 groups with monomers having two LG2 groups can be used to produce linear polymers whereas reactions in which a monomer has three or more LG1 or LG2 groups can be used to produce branched polymers.

Preferably, one of LG1 and LG2 is bromine or iodine and the other is a boronic acid or boronic ester.

Exemplary boronic esters have formula (III):

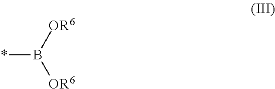

wherein R⁶ in each occurrence is independently a C₁₋₂₀ alkyl group, * represents the point of attachment of the boronic ester to an aromatic ring of the monomer, and the two groups R⁶ may be linked to form a ring. In a preferred embodiment, the two groups R⁶ are linked to form the pinacol ester of boronic acid:

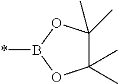 [SMILES: *B1OC(C)(C)C(C)(C)O1]

It will be understood by the skilled person that a monomer containing LG1 leaving groups only will not polymerise to form a direct carbon-carbon bond with another monomer containing LG1 leaving groups, and a monomer containing LG2 leaving groups only will not polymerise to form a direct carbon-carbon bond with another monomer containing LG2 leaving groups. Accordingly, the monomers substituted with LG1 and LG2 groups may be selected to control arrangement of repeat units within each block.

The block copolymer may be formed by reacting monomers to form blocks of varying length that are to form one of the first and second blocks and then reacting these blocks with monomers for forming the other of the first and second blocks.

The reaction is suitably carried out in the presence of a palladium compound catalyst.

The LG1:LG2 monomer molar ratio in the monomers used to form the initially formed block is not stoichiometric. Optionally, the LG1:LG2 ratio is in the range of 40:60-47:53, optionally 42.5:57.5-45:55.

It will be understood that excess monomer present in the mixture used to form the initially formed (first or second) block may be incorporated into the other of the first and second block.

Following formation of the first or second block, the LG1:LG2 monomer molar ratio used to form the other of the first and second block may be stochiometric or an excess of one of these monomers may be provided. Optionally, the molar ratio is in the range of 45:55-55:45.

The overall LG1:LG2 monomer molar ratio of all monomers used to form the polymer may be stoichiometric or may be in the range of 45:55-55:45, optionally 49:51-51:49. An overall ratio that is non-stoichiometric may be used to lower molecular weight of the polymer as compared to an overall stoichiometric ratio.

It will be understood that repeat units illustrated throughout this application may be derived from a monomer carrying suitable leaving groups. Likewise, an end-capping group or side group carrying only one reactive leaving group may be bound to the polymer by reaction of a leaving group at the polymer chain end or side respectively.

Ink Formulation

An ink formulation may be formed by dissolving the polymer of the first aspect in a solvent or solvent mixture, which may be used to form a film of the polymer by a coating or printing method as described herein.

Exemplary solvents are benzenes substituted with one or more substituents selected from C₁₋₁₀ alkyl, C₁₋₁₀ alkoxy and chlorine, for example toluene, xylenes and methylanisoles, and mixtures thereof.

Light-Emitting Layers

A light-emitting layer of an OLED may be unpatterned, or may be patterned to form discrete pixels. Each pixel may be further divided into subpixels. The light-emitting layer may contain a single light-emitting material, for example for a monochrome display or other monochrome device, or may contain materials emitting different colours, in particular red, green and blue light-emitting materials for a full-colour display.

A polymer as described herein may be provided as a light-emitting material in a light-emitting layer, or as a host for a fluorescent or phosphorescent dopant.

If the polymer is used as a host material for a fluorescent or phosphorescent dopant then the lowest singlet excited state energy level or lowest triplet excited state energy level respectively of the polymer is preferably at least the same as, or no lower than, the corresponding energy level of the dopant.

Light emitted from a light-emitting layer, either from the polymer, a light-emitting dopant used in combination with the polymer, or another light-emitting material, may be red, green or blue.

A blue emitting material may have a photoluminescent spectrum with a peak in the range of no more than 490 nm, optionally in the range of 420-480 nm.

A green emitting material may have a photoluminescent spectrum with a peak in the range of more than 490 nm up to 580 nm, optionally more than 490 nm up to 540 nm.

A red emitting material may optionally have a peak in its photoluminescent spectrum of more than 580 nm up to 630 nm, optionally 585-625 nm.

Preferably, the polymer as described herein is a blue fluorescent polymer.

A light-emitting layer may contain a mixture of more than one light-emitting material, for example a mixture of light-emitting materials that together provide white light emission.

The photoluminescence spectrum of a material may be measured by casting a film of the material onto a quartz substrate to achieve transmittance values of 0.3-0.4 and measuring in a nitrogen environment using apparatus C9920-02 supplied by Hamamatsu.

A white-emitting OLED may contain a single, white-emitting layer or may contain two or more layers that emit different colours which, in combination, produce white light. White light may be produced from a combination of red, green and blue light-emitting materials provided in a single light-emitting layer distributed within two or more light-emitting layers.

The light emitted from a white-emitting OLED may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-4500K.

Exemplary phosphorescent light-emitting materials are transition metal complexes of metals and metal ions, preferably metal or metal ions of ruthenium, rhodium, palladium, rhenium, osmium, iridium, platinum and gold. Iridium is particularly preferred.

A phosphorescent light-emitting material may be physically mixed with a host material or may be covalently bound thereto. If the polymer is used as a host material then the phosphorescent light-emitting material may be provided in a side-chain, main chain or end-group of the polymer. Where the phosphorescent material is provided in a polymer side-chain, the phosphorescent material may be directly bound to the backbone of the polymer or spaced apart there from by a spacer group, for example a C₁₋₂₀ alkyl spacer group in which one or more non-adjacent C atoms may be replaced by O or S.

Charge Transporting and Charge Blocking Layers

A hole transporting layer may be provided between the anode and the light-emitting layer or layers of an OLED. Likewise, an electron transporting layer may be provided between the cathode and the light-emitting layer or layers.

Similarly, an electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

A charge-transporting layer or charge-blocking layer may be cross-linked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group.

If present, a hole transporting layer located between the anode and the light-emitting layers preferably has a HOMO level of less than or equal to 5.5 eV, more preferably around 4.8-5.5 eV or 5.1-5.3 eV as measured by cyclic voltammetry. The HOMO level of the hole transport layer may be selected so as to be within 0.2 eV, optionally within 0.1 eV, of an adjacent layer (such as a light-emitting layer) in order to provide a small barrier to hole transport between these layers.

If present, an electron transporting layer located between the light-emitting layers and cathode preferably has a LUMO level of around 2.5-3.5 eV as measured by cyclic voltammetry. For example, a layer of a silicon monoxide or silicon dioxide or other thin dielectric layer having thickness in the range of 0.2-2 nm may be provided between the light-emitting layer nearest the cathode and the cathode. HOMO and LUMO levels may be measured using cyclic voltammetry.

A hole transporting layer may contain a hole transporting polymer comprising repeat units of formula (II), optionally a hole transporting polymer comprising repeat units of formula (II) and one or more arylene repeat units. Arylene repeat units may be as described anywhere herein. One or more of the repeat units of this hole-transporting polymer may be substituted with a crosslinkable group.

Hole Injection Layers

A conductive hole injection layer, which may be formed from a conductive organic or inorganic material, may be provided between the anode 101 and the light-emitting layer 103 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

Cathode

The cathode 105 is selected from materials that have a workfunction allowing injection of electrons into the light-emitting layer of the OLED. Other factors influence the selection of the cathode such as the possibility of adverse interactions between the cathode and the light-emitting material. The cathode may consist of a single material such as a layer of aluminium. Alternatively, it may comprise a plurality of conductive materials such as metals, for example a bilayer of a low workfunction material and a high workfunction material such as calcium and aluminium, for examples disclosed in WO 98/10621. The cathode may comprise elemental barium, for example as disclosed in WO 98/57381, Appl. Phys. Lett. 2002, 81(4), 634 and WO 02/84759. The cathode may comprise a thin (e.g. 1-5 nm) layer of metal compound, in particular an oxide or fluoride of an alkali or alkali earth metal, between the organic layers of the device and one or more conductive cathode layers to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Encapsulation

Organic optoelectronic devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### EXAMPLES

### Polymer Example 1

A polymer was prepared by polymerisation of the following monomers as described in WO 00/53656, the contents of which are incorporated herein by reference, according to the following procedure:

A first block was formed by polymerising a fluorene diboronic ester monomer (2.04 mmol) for forming a repeat unit of formula (VIIa); a dibromofluorene monomer (1.14 mmol) for forming a repeat unit of formula (VIIa); and a dibromo-9,10-dialkylphenanthrene monomer (1.5 mmol) for forming a repeat unit of formula (Ia) for 2 hours.

A second block was formed by adding to the polymerisation mixture a fluorene diboronic ester monomer (between 0.89 and 0.90 mmol) for forming a repeat unit of formula (VIIa); a dibromo monomer (0.24 mmol) for forming a repeat unit of formula (II-1) and a dibromo monomer (0.12 mmol for forming a repeat unit of formula (II-3). The reaction was continued for a further 3 hours.

Comparative Polymer 1

A polymer was prepared as described for Polymer Example 1 except that the monomers used to form the first and second blocks were reacted together at the same time to form a non-block-like copolymer.

### Ink Examples

Ink Example 1 was formed by dissolving 1 wt/v % Polymer Example 1 in a solvent mixture of 80 v/v % cyclohexylbenzene and 20 v/v % 4-methylanisole.

For the purpose of comparison, Comparative Ink 1 was formed in the same way by dissolving Comparative Polymer 1.

The inks were passed through a PTFE filter having 0.05 micron pores using a pressurised filtration rig (0.08 MPa constant pressure).

After 400 minutes, 12 ml of Comparative Ink had been filtered whereas about 17 ml of Ink Example 1 in this time. Without wishing to be bound by any theory, it is believed that Ink Examples 1-3 aggregate to a lesser extent than Comparative Polymer 1 in Comparative Ink 1. Aggregation of the polymer may lead poor stability of the ink due to gel formation within the ink.

### Device Example 1

A blue fluorescent organic light-emitting device having the following structure was prepared:

ITO/HIL/HTL/LE/Cathode,

wherein ITO is an indium-tin oxide anode; HIL is a hole-injecting layer; HTL is a hole-transporting layer; LE is a light-emitting layer; and the cathode comprises a layer of sodium fluoride in contact with the light-emitting layer, a layer of aluminium and a layer of silver.

To form the device, a substrate carrying ITO was cleaned using UV/Ozone. The hole injection layer was formed by spin-coating an aqueous formulation of a hole-injection material available from Nissan Chemical Industries and heating the resultant layer. The hole transporting layer was formed by spin-coating Hole-Transporting Polymer 1 and crosslinking the polymer by heating. The light-emitting layer was formed by spin-coating Polymer Example 1. The cathode was formed by evaporation of a first layer of sodium fluoride to a thickness of about 2 nm, a second layer of aluminium to a thickness of about 100 nm and a third layer of silver to a thickness of about 100 nm.

Hole-Transporting Polymer 1 comprises phenylene repeat units of formula (VIa), amine repeat units of formula (II-1) and crosslinkable repeat units of formula (VIIa) and crosslinking the polymer by heating.

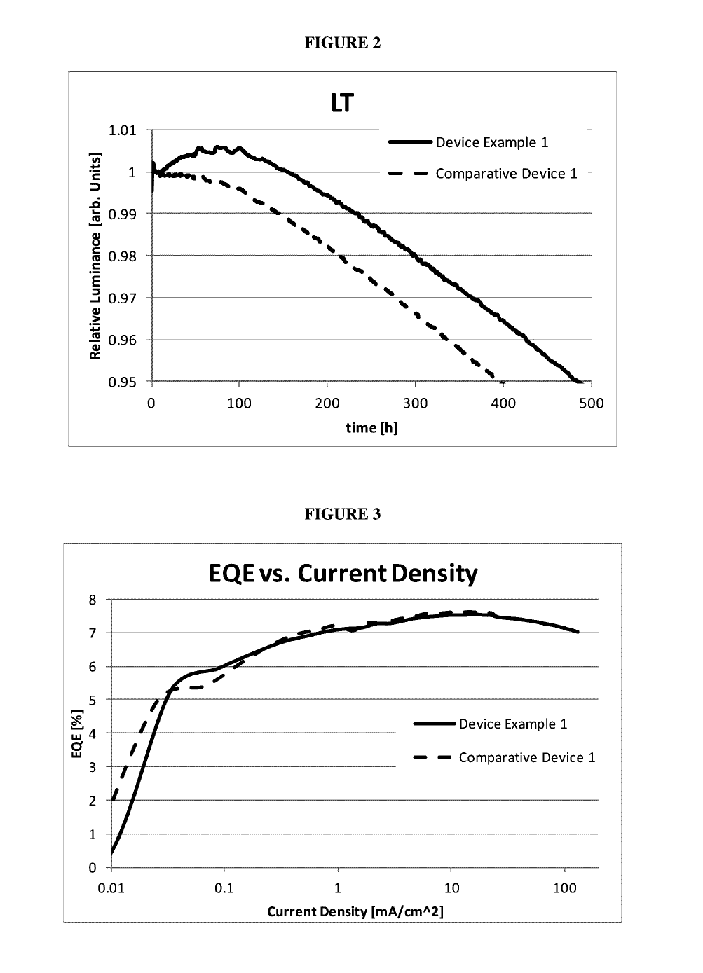

With reference to FIG. 2, Device Example 1 has a longer T95 lifetime than that of Comparative Device 1, wherein T95 is the time take for luminance of the device to fall to 95% of an initial value at constant current.

With reference to FIG. 3, Device Example 1 and Comparative Device 1 have similar external quantum efficiencies.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A block copolymer comprising a first block and a second block wherein the first block comprises a repeat unit of formula (I) and the second block comprises a repeat unit of formula (II): 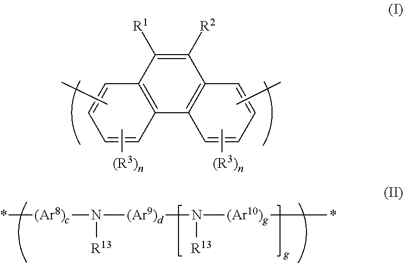
wherein R¹ and R² are independently H or a substituent;
R³ independently in each occurrence is a substituent;
each n is independently 0, 1, 2 or 3;
Ar⁸, Ar⁹ and Ar¹⁰ independently in each occurrence is an aryl or heteroaryl group that may be unsubstituted or substituted with one or more substituents;
R¹³ independently in each occurrence is a substituent;
c, d and e are each independently at least 1; and
g is 0 or a positive integer.

2. A block copolymer according to claim 1 wherein the first block is free of repeat units of formula (II).

3. A block copolymer according to claim 1 wherein the first block consists essentially of repeat units of formula (I) and optionally one or more repeat units of formula Ar wherein Ar is an arylene or heteroarylene repeat unit other than a repeat unit of formula (I) that may be unsubstituted or substituted with one or more substituents.

4. A block copolymer according to claim 1 wherein the second block is free of repeat units of formula (I).

5. A block copolymer according to claim 4 wherein the second block comprises one or more repeat units of formula Ar wherein Ar is an arylene or heteroarylene repeat unit other than a repeat unit of formula (I) that may be unsubstituted or substituted with one or more substituents.

6. A method of forming a block copolymer according to claim 1 wherein monomers for forming one of the first and second blocks are reacted to form said first or second block, and reacting said first or second block with monomers for forming the other of the first and second block.

7. A method according to claim 6 wherein each of the first and second blocks are formed by reacting monomers having leaving groups LG1 with monomers having leaving groups LG2.

8. A method according to claim 7 wherein each LG1 is independently a boronic acid or ester thereof, and each LG2 is independently a halogen or sulfonic acid or ester thereof.

9. An organic electronic device comprising an anode, a cathode and at least one organic semiconducting layer between the anode and cathode wherein at least one of the organic semiconducting layers comprises a block copolymer according to claim 1.

10. An organic electronic device according to claim 9 wherein the device is an organic light-emitting device and at least one of the organic semiconducting layers is a light-emitting layer.

11. An organic light-emitting device according to claim 9 wherein the light-emitting layer comprises a block copolymer.

12. An organic light-emitting device according to claim 11 wherein the block copolymer is a blue light-emitting polymer.

13. An ink formulation comprising a block copolymer according to claim 1 and at least one solvent.

14. A method of forming an organic electronic device according to claim 9, the method comprising the step of forming an organic semiconducting layer of the device by depositing an ink.

15. A method according to claim 14 wherein the ink is deposited by ink jet printing.
